(19) United States
(12) Patent Application Publication
(10) Pub. No.: US 2009/0189611 A1
(43) Pub. Date: Jul. 30, 2009

(54) MAGNETIC RESONANCE IMAGING SYSTEM WITH REDUCED UNINTENTIONAL MECHANICAL MOVEMENTS

(75) Inventors: Nicolaas Bernardus Roozen, Eindhoven (NL); Erik Johannes Maria Janssen, Eindhoven (NL); Georgo Zorz Angelis, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/438,146

(22) PCT Filed: Aug. 20, 2007
(86) PCT No.: PCT/IB2007/053306

§ 371 Date: Feb. 20, 2009

(30) Foreign Application Priority Data
Aug. 22, 2006 (EP) 06119278.7

(51) Int. Cl. G01R 33/28

(52) U.S. Cl. 324/322

(57) ABSTRACT

A magnetic resonance imaging (MRI) system (1) with an active vibration control is provided, in that a number of piezo-electric actuators (6) are positioned between at least one element (2, 3, 5, 9, 10) of the MRI system (1) and an associated support surface (8) and being connected in series with each other; and a control unit (11, 11′) is adapted to actively control the displacement of the number of piezo-electric actuators (6) in a way that unintentional mechanical movements of the MRI system (1) are reduced.

### FIELD OF THE INVENTION

The present invention relates to a magnetic resonance imaging (MRI) system, in which unintentional mechanical movements of the MRI system are reduced. Furthermore the present invention relates to a method of operating such a MRI system and to a computer program for controlling such a MRI system.

During operation of certain types of MRI systems problems arise because of unintentional mechanical movements of the MRI system. During switching of gradient coils in the MRI system Lorenz-forces are generated, which causes mechanical vibrations. In this invention the focus is on the low frequency vibrations below 100 Hz, typically in the region of 10-25 Hz. For example in open type MRI systems the upper and the lower part of the system is moving with respect to each other with a frequency of 10-25 Hz. These vibrations cause eddy currents in material components in the main magnetic field of the MRI system. These eddy currents pass through resistive material, and generate heat that causes evaporation of liquid Helium from the MRI system's cryostat. This evaporation of liquid Helium due to eddy currents is usually indicated as “dynamic boil-off”. Moreover, the eddy currents create varying magnetic fields which distort the gradient encoding of the magnetic resonance signals and ultimately are the cause of deterioration of image quality. Eddy currents are for example the reason of ghosting phenomena. Mechanical vibrations and their consequences are particularly a problem for open type MRI systems, which are not only more vulnerable to internal excitation by the gradient-coil, especially in the mentioned low frequency range, but also to floor vibrations.

### BACKGROUND OF THE INVENTION

From the international patent application WO 2002/46783 A1 it is known to reduce acoustic noise by neutralize forces between a gradient coil arrangement and a support structure of a MRI system. For this purpose an active element is provided between the support structure and the gradient coil arrangement. However, no solution is given for the problem of reducing the dominant vibrational displacements in case of certain operation modes of the MRI system, e.g. the 25 Hz operation mode, that contribute to reduced image quality.

### SUMMARY OF THE INVENTION

It is an object of the present invention to provide a simple and reliable technique for reducing unintentional mechanical movements in a MRI system with a support structure for supporting at least one element of the system.

This object is achieved according to the invention by a MRI system, comprising a number of piezo-electric actuators, the number of piezo-electric actuators being positioned between at least one element of the MRI system and an associated support surface and being connected in series with each other; and a control unit adapted to actively control the displacement of the number of piezo-electric actuators in a way that unintentional mechanical movements of the MRI system are reduced.

The object of the present invention is also achieved by a method of operating a MRI system, the MRI system comprising a number of piezo-electric actuators, the number of piezo-electric actuators being positioned between at least one element of the MRI system and an associated support surface and being connected in series with each other; and a control unit, the method comprising the step of actively controlling by means of the control unit the displacement of the number of piezo-electric actuators in a way that unintentional mechanical movements of the MRI system are reduced.

The object of the present invention is also achieved by a computer program for controlling a MRI system, the MRI system comprising a number of piezo-electric actuators, the number of piezo-electric actuators being positioned between at least one element of the MRI system and an associated support surface and being connected in series with each other; and a control unit for controlling the displacement of the number of piezo-electric actuators, the computer program to be executed in a computer comprising computer program instructions to actively control the displacement of the number of piezo-electric actuators in a way that unintentional mechanical movements of the MRI system are reduced, when the computer program is executed in the computer. The technical effects necessary according to the invention can thus be realized on the basis of the instructions of the computer program in accordance with the invention. Such a computer program can be stored on a carrier such as a CD-ROM or it can be available over the internet or another computer network. Prior to executing the computer program is loaded into the computer by reading the computer program from the carrier, for example by means of a CD-ROM player, or from the internet, and storing it in the memory of the computer. The computer includes amongst others a central processor unit (CPU), a bus system, memory means, e.g. RAM or ROM etc., storage means, e.g. floppy disk or hard disk units etc. and input/output units. Alternatively, the inventive method could be implemented in hardware, e.g. using one or more integrated circuits.

A core idea of the invention is to employ piezo-electric actuators and to actively control these piezo-electric actuators in a way that the unintentional mechanical movements of the MRI system are reduced. In other words, an active vibration control technique is suggested, in which piezo-electric actuators are used. The piezo-electric actuators are employed to damp or reduce the low-frequency mechanical vibrations of the MRI system. For this purpose the piezo-electric actuators are provided between at least one element of the MRI system and the support surface; in other words, the weight of the MRI system is carried by the piezo-electric actuators. The piezo-electric actuators are connected in series with the at least one element of the MRI system on the one hand and with the support surface on the other hand. The piezo-electric actuators can be connected for example to a support structure of the MRI system, e.g. to a number of supporting stands. Alternatively the piezo-electric actuators can be connected directly to the gradient coil arrangement or to the magnets of the MRI system.

With the present invention unintentional internal mechanical movements of the MRI system, e.g. vibrations, can be reduced using an active control strategy. At the same time movements of the MRI system which are caused by vibrations of the support surface (e.g. the floor upon which the MRI system is positioned) can actively be reduced. With this simple and reliable technique quality problems of the measurement results can be avoided. In particular the problem of dynamic boil-off of liquid Helium as well as the problem of image quality in a MRI system can be overcome.

The use of piezo-electric actuators is advantageous because of its inherent stiffniess. Piezo-electric actuators are especially well suited for MRI systems, since they both withstand the high static magnetic field and do not generate magnetic field variations, which would cause image quality problems.

These and other aspects of the invention will be further elaborated on the basis of the following embodiments which are defined in the dependent claims.

According to a preferred embodiment of the invention the use of a number of resilient elements is suggested. These resilient elements serve in combination with the piezo-electric actuators to damp or reduce the low-frequency mechanical vibrations of the MRI system. The resilient elements as well as the cooperating piezo-electric actuators are positioned in series between the at least one element of the MRI system and the associated support surface and are adapted to each other in a way that their resulting effective stiffniess is low or very low, e.g. almost zero, at low vibrational frequencies (typically below 100 Hz), whereas the static stiffness is high to support the weight of the MRI system. Furthermore, with the use of resilient element, vibrations at higher frequencies can be isolated.

The piezo-electric actuators can be controlled in order to reduce the movements of MRI system in two different ways. In a first way, according to a preferred embodiment of the invention, the displacement of the number of piezo-electric actuators is controlled by means of the control unit in a way that the unintentional mechanical movements of the system are damped. The control unit is adapted accordingly. Preferably, this is achieved by controlling the displacement of the number of piezo-electric actuators based on a signal representing the current mechanical movements of the system. In other words the piezo-electric actuators are controlled by using a “feed-back” or “closed loop” mode. The necessary signal is acquired by means of at least one corresponding sensor. As sensors, preferably piezo-electric sensors are used. However, other sensor types, such as accelerometers, strain gauges and the like can be used likewise. These sensors are preferably positioned in a way that the current mechanical movements of the system, e.g. information about the current position, the acceleration and/or the vibration frequency, can reliably be determined. The sensor position depends strongly on the type of sensor used.

In this embodiment of the invention a feedback signal is applied to the piezo-electric actuators, which as a result generate a corresponding displacement resulting in a feedback force to be applied to the MRI system. In that way a damping is introduced in the system, thereby lowering the vibration level.

This feedback control strategy, which uses the response of the MRI system for controlling the piezo-electric actuators, can also be used for unknown disturbances, e.g. in cases where the mechanical movements of the MRI system changes over time. Using this first way of controlling the piezo-electric actuators, a vibration reduction factor of about 4 can be reached.

In a second way, according to a preferred embodiment of the invention, the displacement of the number of piezo-electric actuators is controlled by means of the control unit in a way the unintentional mechanical movements of the system are counteracted. The control unit is adapted accordingly. Preferably, this is achieved by controlling the displacement of the number of piezo-electric actuators based on a signal representing the performance of the MRI system. The signal representing the performance of the system is a one-time signal, or a signal to be used in defined intervals, but no current signal. In other words the piezo-electric actuators are controlled by using a “feed-forward” or “open loop” mode, without a permanent feedback signaling.

The signal representing the performance of the MRI system can relate to the current mechanical movements of the system, as described above. The same kind of sensors can be employed.

The signal representing the performance of the MRI system can also relate to other informations representing the performance of the MRI system, e.g. the quality of the measurement results. Preferably, the signal representing the performance can relate to the image quality, which has to be analyzed in order to obtain the required signal.

In this embodiment of the invention no feedback signal is applied to the piezo-electric actuators. Instead an initiating signal is provided, according to which a force is applied to the MRI system. By this means a counteracting force is introduced in the system in a way that the movement of the MRI system is counteracted. This feed-forward control strategy cannot be used for unknown disturbances. However, this embodiment is easier and cheaper to implement, because no feedback loops have to be established. Using this second way of controlling the piezo-electric actuators, a vibration reduction factor of 10 and more can be reached.

Both ways of controlling the piezo-electric actuators are complementary. However, if the unintentional mechanical movements do change over time (frequency shift), the first way is preferred.

Both methods can be combined to arrive at a so-called adaptive feed forward approach, in which an error signal is used to adapt the feed forward controller. This method combines the advantages of the feed forward and feedback approaches, having a performance comparable of the feed forward approach and the robustness against changes in the dynamics of the system (e.g. due to temperature fluctuation) of the feedback approach.

### BRIEF DESCRIPTION OF THE FIGURES

These and other aspects of the invention will be described in detail hereinafter, by way of example, with reference to the following embodiments and the accompanying drawings; in which:

FIG. 1 shows a schematic illustration of a first embodiment of a MRI scanner (side view),

FIG. 2 shows a schematic illustration of a first embodiment of the MRI scanner (top view),

FIG. 3 shows a schematic block diagram of the MRI scanner and a control unit according to a first embodiment of the invention,

FIG. 4 shows an uncontrolled dynamic response for a scanning sequence,

FIG. 5 shows a controlled dynamic response for a scanning sequence,

FIG. 6 shows a schematic illustration of a second embodiment of a MRI scanner (side view).

FIG. 7 shows a schematic illustration of a third embodiment of a MRI scanner (side view),

FIG. 8 shows a schematic illustration of a third embodiment of the MRI scanner (top view),

FIG. 9 shows a schematic block diagram of the MRI scanner and a control unit according to a third embodiment of the invention.

### DETAILED DESCRIPTION OF THE EMBODIMENTS

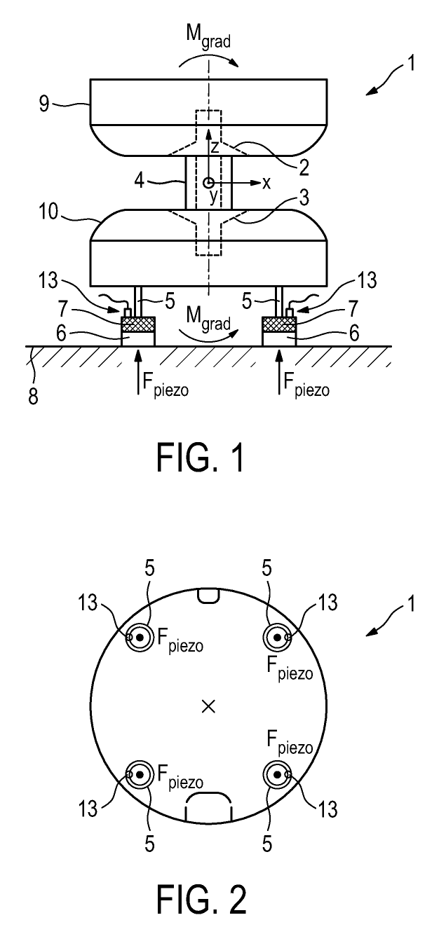

FIGS. 1 and 2 illustrate a first embodiment of the invention in form of a high field open (HFO) MRI scanner 1 with an upper gradient coil arrangement 2 and an lower gradient coil arrangement 3, connected to each other by means of a post 4. The resonance frequency of the MRI scanner 1 is around 25 Hz. The scanner is loaded by two moments M_{grad} around the Y-axis on the upper side and lower side respectively by switching the X-gradient coils. The MRI scanner 1 comprising magnets 9, 10 and the gradient coil arrangement 2, 3 is supported by a support structure in form of four supporting stands 5. Each stand 5 is connected in series with a resilient suspension element and a piezo-electric actuator 6. The resilient suspension element is provided in form of a rubber mount 7 serving as a vibration isolation device. Of course, other materials and other designs can be used for the resilient element. The four piezo-electric actuators 6 resting on a buildings floor 8. In other words, the combinations of rubber mount 7 and cooperating piezo-electric actuator 6 carry the total weight of the MRI scanner 1, for which purpose the piezo-electric actuators 6 are selected to be stiff enough. The rubber mounts 7 are compliant with respect to the large weight of the MRI scanner 1. In an alternative embodiment of the invention (not shown) no supporting stands 5 are provided. In this case, the MRI scanner 1 rests on the piezo-electric actuators 6 without an intermediate support structure.

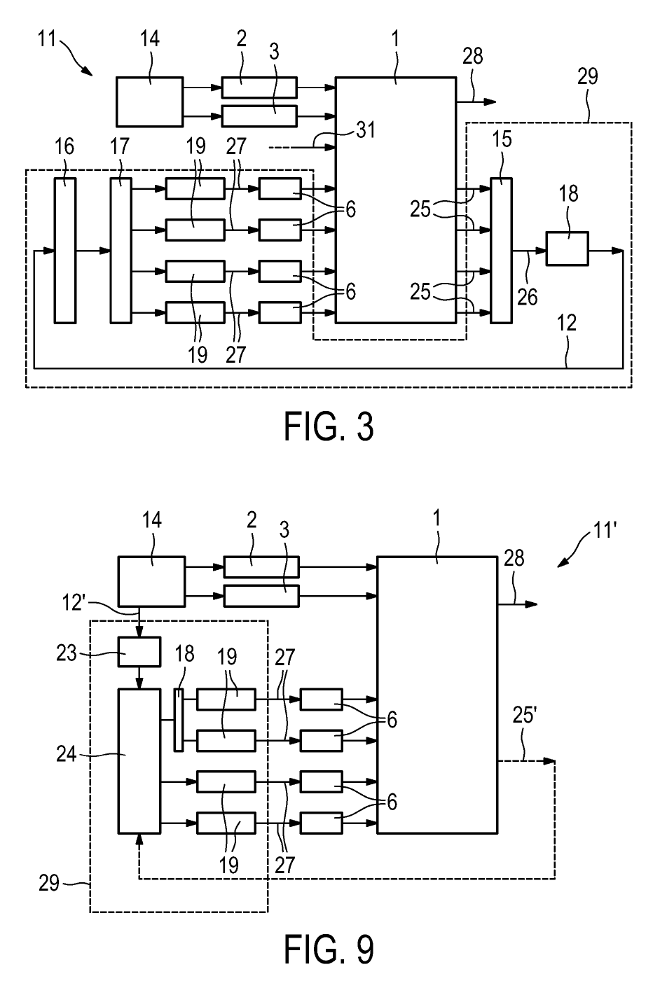

A control unit 11 is provided, see FIG. 3, to actively control the displacement of the number of piezo-electric actuators 6. In the embodiment illustrated in FIG. 1 to 3, a “feed-back” or “closed loop” control mode is implemented, during which the four piezo-electric actuators 6 are controlled in a way that the unintentional mechanical movements of the MRI scanner 1 are damped. For this purpose the control unit 11 controls the displacement of the four piezo-electric actuators 6 corresponding to a control signal 12 representing the current mechanical movements of the MRI scanner 1. An accelerometer 13 is positioned on top of each rubber mount 7. The accelerometers 13 send signals corresponding to the current accelerations of the MRI scanner 1 to the control unit 11. According to these feedback signals the control unit 11 controls the piezo-electric actuators 6 such that a defined feedback force F_{piezo} is applied to the rubber mounts 7, thereby lowering the vibration level, i.e. damping the MRI scanner 1. The piezo-electric actuators 6 are connected in such a way, that the motion direction of all actuators 6 are identical towards to rubber mounts 7.

The operation of the control unit 11 is now described in more detail. The MRI scanner 1 is operated in it's 25 Hz operating mode (other operating modes are available, e.g. at 60 Hz, 100 Hz etc.). The MRI scanner 1 is excited due to a control sequence that is applied to the system via a signal generator 14. As a result i.e. the X-gradient coils are switched. At the same time floor vibrations 31 may influence the movements of the MRI system 1. The control unit 11 implements a feedback control loop, which comprises a sensor transformation element 15, a single input single output (SISO) controller 16 and an actuator transformation element 17. The sensor transformation element 15 transforms acceleration sensor signals 25 into a single observation signal 26, which is inverted by means of an inverter 18 and fed as control signal 12 to the SISO controller 16. Since the SISO controller 16 is preferably implemented in software and/or digital electronics, the sensor transformation element 15 comprises an analog-digital converter function to convert the analog accelerations sensor signals 25 into the single observation signal 26. The SISO controller 16 processes the control signal 12 to control the piezo-electric actuators 6 via an actuator transformation element 17. The actuator transformation element 17 transforms the single output signal of the SISO controller 16 into four separate control signals for each piezo-electric actuator 6. For this purpose the actuator transformation element 17 comprises a digital-analog converter function to convert the digital the output signal of the SISO controller 16 into four separate control signals. To the actuator transformation element 17 four amplifier 19 are connected, each of which is connected to one piezo-electric actuator 6. For generating a desired displacement of the piezo-electric actuators 6, control voltages 27 are applied by the amplifiers 19 to the actuators 6. Alternatively four separate SISO-controllers (not shown), one for each piezo-electrical actuator 6, can be used. Thus, a multi loop SISO control is implemented, in during which each measured acceleration is directly paired with a piezo-electrical actuator 6 via a dedicated SISO controller 16. In this way, four independent control loops are provided. The SISO controller(s), sensor transformation elements and actuator transformation elements can also be implemented as analog electronics or a combination of digital and analog electronics.

The forces generated by means of the piezo-electric actuators 6 are limited. In an example the maximum control force F_{control, max} results from

F_{control,max}=Δx_{piezo,max}·cₘₒᵤₙₜ≈5·10⁻⁶·1·10⁶=5N

in which ΔX_{piezo, max} denotes the maximum displacement of a piezo-electric actuator 6 (e.g. ±5 μm) and cₐₘₒᵤₙₜ denotes the stiffness of the rubber mounts 7 (e.g. 10⁶ N/m).

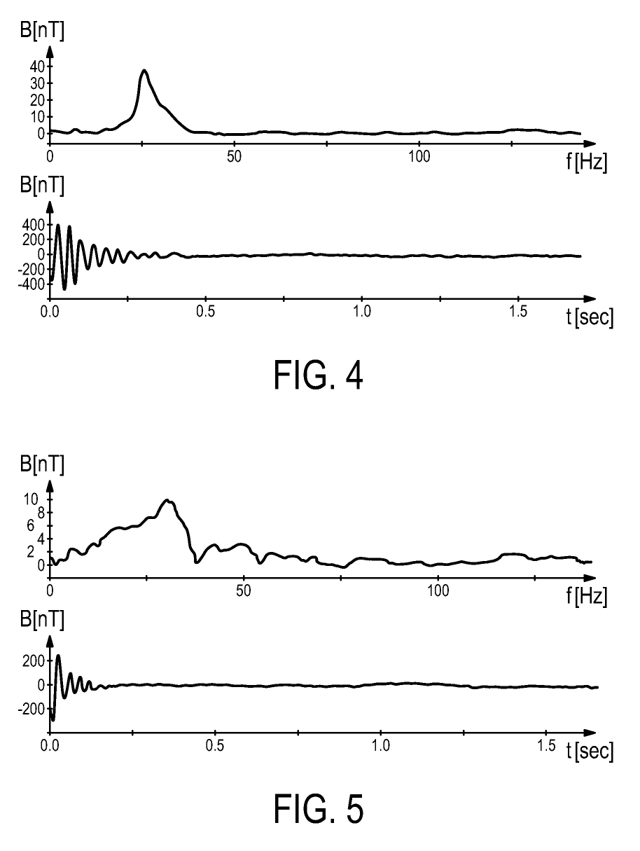

The performance of the MRI scanner 1 can for example be monitored by measuring field variations 28. For FIGS. 4 and 5 the field variations are measured without and with applying feedback control. In FIGS. 4 and 5 the dynamic response for a scanning sequence is shown, using a control unit with only one SISO controller 16. The Figs. illustrate the pulse response generated by the X-gradient coils of magnetic fields variations. The settling time is reduced around four times and the maximum frequency amplitude is also decreased by a factor four. The acceleration level is reduced by 13 dB at 25 Hz. In other words, the control unit 11 solves the problem of resonance, by making the feedback forces function in such a way that damping is created and no resonance occurs.

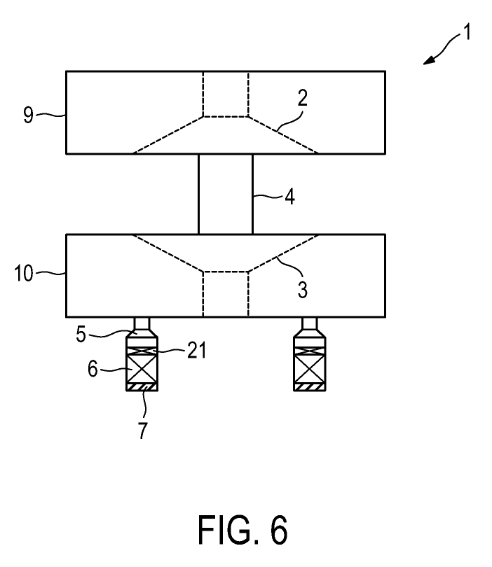

FIG. 6 illustrates a second embodiment of the invention. Again a HFO MRI scanner 1 with an upper and a lower gradient coil arrangement 2, 3 are shown and the same feedback control strategy is applied. In contrast to the embodiment described above, another type of sensor is provided. Instead of accelerometer sensors 13 mounted on top of the rubber mounts 7, four piezo-electric sensors 21 are provided, adapted to sense movements of the MRI scanner 1. Each of these sensors 21 is mounted in series between a piezo-electric actuator 6 and a stand 5. Each stand 5 is completed by a resilient element, e.g. a rubber mount 7, positioned between the piezo-electric actuator 6 and the floor 8. Thus, in this second embodiment, there are sensing piezo-electric elements 21 and actuating piezo-electric elements 6, and the resulting voltage generated by the sensing piezo-electric elements 21 can be used as a proportional signal to control the actuating piezo-electric elements 6.

These two embodiments describe a very robust way of dealing with the 25 Hz operating mode of the MRI scanner 1. Furthermore these embodiments are very useful in cases where the frequency shifts. These embodiments can e.g. be used in case of different operating modes (e.g. 60 Hz, 100 Hz etc).

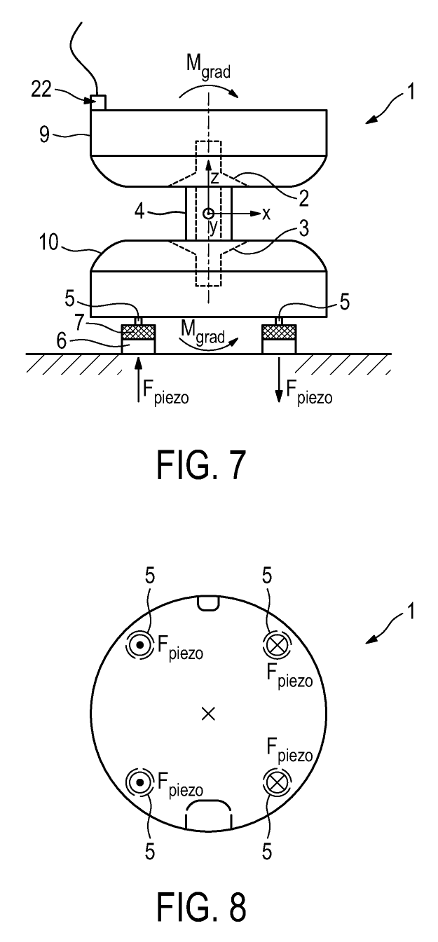

FIGS. 7 and 8 illustrate a third embodiment of the invention, again in form of a HFO MRI scanner 1 with an upper and a lower gradient coil arrangement 2, 3. The construction of this MRI scanner 1 is basically the same as in the first embodiment. However, another control unit 11′ is provided, implementing another control strategy of the piezo-electric actuators 6. In this embodiment a “feed-forward” or “open loop” control mode is implemented, during which the four piezo-electric actuators 6 are controlled in a way that the unintentional mechanical movements of the MRI scanner 1 are counteracted. Furthermore the piezo-electric actuators 6 are connected in such a way, that the motion direction of two neighboring actuators is reversed with respect to the motion direction of the other two actuators. In other words, two of the actuators 6 are mounted such that the motion direction is directed towards the floor 8 and the other two actuators 6 are mounted such that the motion direction is directed towards the rubber mounts 7. In this way the piezo-electric actuators 6 can effectively counteract the mode-excitation at 25 Hz by the gradient coils, if the amplitude of the actuator's displacement is accurately tuned relative to the amplitude of the scanner's unintentional movement.

The control unit 11′ controls the piezo-electric actuators 6 according to an acceleration sensor signal 25′ representing the performance of the MRI scanner 1, which is obtained by means of an accelerometer sensor 22 mounted on top of the upper gradient arrangement 2, measuring the accelerations in Z-direction. Here, prior to starting the active vibration control a one-time measurement of the scanner's movement is carried out by means of the accelerometer 22. Based on this signal 25′ the phase of the unintentional movement of the MRI scanner 1 is determined in a one-time setup procedure and the phase of the counterforce to be generated by means of the piezo-electric actuators 6 is tuned with respect to this determined phase such that a reduced acceleration, i.e. a reduced movement of the MRI scanner 1 is obtained. In other words, from the measured information a 25 Hz movement is obtained and fed back via the control unit 11′ to the piezo-electric actuators 6. By this means an unintentional amplifying of scanner movements at the resonance frequency can be avoided.

The operation of the control unit 11′ during the one-time setup procedure is now described in more detail with reference to FIG. 9. The MRI scanner 1 is excited due to a control sequence that is applied to the system via a signal generator 14. The same signal, which is used to control the X-gradient coils, is now used as control signal 12′ for the piezo-electric actuators 6. The control signal 12′ is filtered by means of a very narrow band-filter 23, leaving only the signal around 25 Hz which actually causes the image problems. Next, a phase compensation is carried out in a phase controller 24, as described above. Then this signal is fed to four amplifiers 19, to which the piezo-electric actuators 6 are connected. Two of theses signals are inverted beforehand by means of an inverter 18 in order to control the motion direction of two neighboring actuators 6 as described above.

All or at least a number of functions of the control units 11, 11′ are carried out by means of a processing unit 29, which is adapted for performing all tasks of calculating and computing the measured input data as well as determining and assessing results and output data. This is achieved according to the invention by means of a computer software comprising computer instructions adapted for carrying out the steps of the inventive method, when the software is executed in the processing unit. The processing unit itself may comprise functional modules or units, which are implemented in form of hardware, software or in form of a combination of both.

It will be evident to those skilled in the art that the invention is not limited to the details of the foregoing illustrative embodiments, and that the present invention may be embodied in other specific forms without departing from the spirit or essential attributes thereof. The present embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein. It will furthermore be evident that the word “comprising” does not exclude other elements or steps, that the words “a” or “an” do not exclude a plurality, and that a single element, such as a computer system or another unit may fulfil the functions of several means recited in the claims. Any reference signs in the claims shall not be construed as limiting the claim concerned.

### REFERENCE NUMERALS

MRI scanner
upper gradient arrangement
lower gradient arrangement
post
stand
piezo-electric actuator
rubber mount
floor
magnet
magnet
control unit
control signal
accelerometer sensor
signal generator
sensor transformation element
SISO controller
actuator transformation element
inverter
amplifier
(free)
piezo-electric sensor
accelerometer
band filter
phase controller
acceleration sensor signal
observation signal
control voltage
field variation
processing unit
(free)
floor vibrations

1. A magnetic resonance imaging (MRI) system, comprising a number of piezo-electric actuators, the number of piezo-electric actuators being positioned between at least one element of the MRI system and an associated support surface and being connected in series with each other; and a control unit adapted to actively control the displacement of the number of piezo-electric actuators in a way that unintentional mechanical movements of the MRI system are reduced, wherein the control unit is adapted to control the displacement of the number of piezo-electric actuators based on a signal representing the performance of the MRI system.

2. The MRI system as claimed in claim 1, further comprising a number of resilient elements being positioned between the at least one element of the MRI system and the number of piezo-electric actuators and/or between the number of piezo-electric actuators and the associated support surface, and being connected in series with the piezo-electric actuators.

3. The MRI system as claimed in claim 1, wherein the control unit is adapted to control the displacement of the number of piezo-electric actuators in a way that the unintentional mechanical movements of the MRI system are damped.

4. The MRI system as claimed in claim 1, comprising a sensor for acquiring a signal representing the current mechanical movements of the MRI system, and wherein the control unit is adapted to control the displacement of the number of piezo-electric actuators based on said signal.

5. The MRI system as claimed in claim 1, wherein the control unit is adapted to control the displacement of the number of piezo-electric actuators in a way the unintentional mechanical movements of the MRI system are counteracted.

6. (canceled)

7. A method of operating a MRI system, the MRI system comprising a number of piezo-electric actuators, the number of piezo-electric actuators being positioned between at least one element of the MRI system and an associated support surface and being connected in series with each other; and a control unit, the method comprising the step of actively controlling by means of the control unit the displacement of the number of piezoelectric actuators in a way that unintentional mechanical movements of the MRI system are reduced, wherein the control unit is adapted to control the displacement of the number of piezo-electric actuators based on a signal representing the performance of the MRI system.

8. A computer program for controlling a MRI system, the MRI system comprising a number of piezo-electric actuators, and the number of piezo-electric actuators being positioned between the at least one element of the MRI system and an associated support surface and being connected in series with each other; and a control unit for controlling the displacement of the number of piezo-electric actuators, the computer program to be executed in a computer, comprising computer program instructions to actively control the displacement of the number of piezoelectric actuators in a way that unintentional mechanical movements of the MRI system are reduced, the control unit controlling the displacement of the number of piezo-electric actuators based on a signal representing the performance of the MRI system, when the computer program is executed in the computer.

9. The MRI system as claimed in claim 1, wherein the signal representing the performance of the MRI system relates to the quality of the measurement results, preferably to the image quality.
